(19) United States
(12) Patent Application Publication
(10) Pub. No.: US 2025/0048731 A1
(43) Pub. Date: Feb. 6, 2025

(54) DRIVER SUBSTRATE, DISPLAY MODULE AND DISPLAY DEVICE

(71) Applicant: TCL CHINA STAR OPTOELECTRONICS TECHNOLOGY CO., LTD., Shenzhen (CN)

(72) Inventor: Jinfeng Liu, Shenzhen (CN)

(73) Assignee: TCL CHINA STAR OPTOELECTRONICS TECHNOLOGY CO., LTD., Shenzhen (CN)

(21) Appl. No.: 17/296,229

(22) PCT Filed: Mar. 30, 2021
(86) PCT No.: PCT/CN2021/083819

§ 371 Date: May 28, 2024

(30) Foreign Application Priority Data
Feb. 8, 2021 (CN) 202110171201.8

(51) Int. Cl. H01L 27/12

(52) U.S. Cl. CPC H01L 27/1244

(57) ABSTRACT

Embodiments of the present application disclose a driver substrate, a display module and a display device. The drive substrate includes a display area and a fanout area arranged side by side along a first direction. The driver substrate includes a plurality of scan lines and a plurality of data lines located in the display area. Each of the plurality of data lines is connected to a data bridging line, the data lines and the data bridging line are arranged in different layers, one end of the data bridging line is connected to the data line in the display area, and the other end of the data bridging line extends into the fanout area along the first direction.

### FIELD

This application relates to a display field, and particularly to a driver substrate, a display module and a display device.

### BACKGROUND

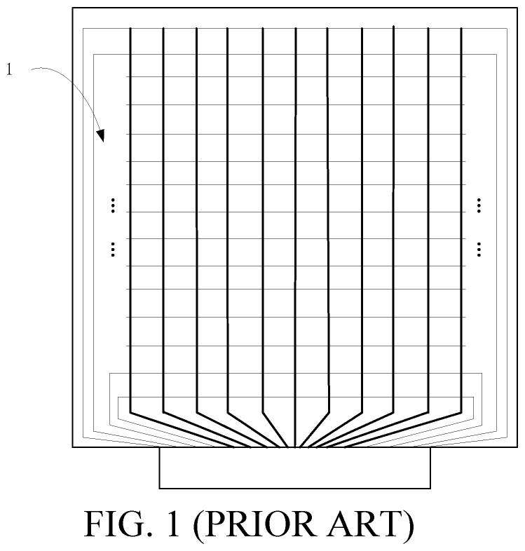

In recent years, market demand has led to vigorous development of panels with a larger size. Due to a size limitations of a glass substrate, splicing screens have been developed. As shown in FIG. 1, a driver substrate for a conventional splicing panel or splicing backlight in the prior art is illustrated. Obviously, due to a great number of data signal lines or driver signal lines is provided on a side of a frame 1 of the driver substrate, a width of a side of each display module in the splicing display is relatively large, resulting in a too large of a seam formed between display areas of two display modules in the splicing display, and causes an unstable image display (i.e., mura) problem of the splicing display, which affects display quality.

### SUMMARY

### Technical Problem

Embodiments of the present application provide a drive substrate, a display module, and a display device, so as to solve a technical problem such as an unstable image display (i.e., mura) problem of a splicing display caused by a too large seam formed between display areas of two display modules in the splicing display due to a great number of data signal lines or driver signal lines is provided on a side of a frame of a driver substrate.

### Solution to Problem

### Technical Solution

Embodiments of the present application provide a drive substrate, comprising a display area and a fanout area arranged side by side along a first direction.

The driver substrate comprises a plurality of scan lines parallel to the first direction and a plurality of data lines parallel to a second direction, the second direction intersects the first direction and is arranged to be aligned with the first direction at a predetermined angle, each of the plurality of scan lines and each of the plurality of data lines are located in the display area, and one end of each of the plurality of scan lines close to the fanout area is provided with a scan trace extending into the fanout area.

Each of the plurality of data lines is connected to a data bridging line, the data lines and the data bridging line are arranged in different layers, one end of the data bridging line is connected to the data line in the display area, and the other end of the data bridging line extends into the fanout area along the first direction.

In the driver substrate provided by the embodiments of the present application, the driver substrate further comprises an insulating layer, each of the plurality of data lines is arranged on one side of the insulating layer, and the data bridging line is arranged on a side of the insulating layer away from the data line.

The insulating layer is defined with a plurality of via holes located in the display area, and each of the plurality of data lines correspondingly passes through one of the plurality of via holes and is connected to the data bridging line.

In the driver substrate provided by the embodiments of the present application, each of the plurality of scan lines is arranged on a side of the insulating layer away from the data line, and each of the plurality of scan lines and the data bridging line are arranged on a same layer as an integrated structure.

In the driver substrate provided by the embodiments of the present application, the driver substrate further comprises a center line parallel to the first direction, each of the plurality of data lines is symmetrically arranged with the center line as a symmetry axis, the plurality of the data lines are divided into a plurality groups of data line in the first direction, and each of the plurality groups of data line comprises at least one of the plurality of data lines.

In two adjacent groups of data line, the via hole corresponding to one of the plurality groups of data line is located on one side of the center line, and the via hole corresponding to the other one of the plurality groups of data line is located on the other side of the center line.

In the driver substrate provided by the embodiments of the present application, the plurality groups of data line comprise one of the plurality of data lines.

Among the two adjacent groups of data line, a distance from the via hole corresponding to one of the plurality groups of data line close to the fanout area to the center line is greater than or equal to a distance from the via hole corresponding to one of the plurality groups of data line away from the fanout area to the center line.

In the driver substrate provided by the embodiments of the present application, the plurality groups of data line comprise at least two of the plurality of data lines.

Among the two adjacent groups of data line, an average distance from each of the plurality of via holes corresponding to one of the plurality groups of data line close to the fanout area to the center line is greater than or equal to an average distance from each of the plurality of via holes corresponding to one of the plurality groups of data line away from the fanout area to the center line.

In the driver substrate provided by the embodiments of the present application, among the two adjacent data lines in each of the plurality groups of data line, a distance from one of the plurality of via holes corresponding to the data line close to the fanout area to the center line is greater than a distance from the center line to one of the plurality of via holes corresponding to the data line away from the fanout area.

In the driver substrate provided by the embodiments of the present application, at least one data bridging line is provided between two adjacent scan lines.

In the driver substrate provided by the embodiments of the present application, the driver substrate further comprises a bending area adjacent to the display area, and the fanout area is located in the bending area.

Embodiments of the present application further provides a display module comprising a driver substrate, wherein the driver substrate comprises a display area and a fanout area arranged side by side along a first direction.

The driver substrate comprises a plurality of scan lines parallel to the first direction and a plurality of data lines parallel to a second direction, the second direction intersects the first direction and is arranged to be aligned with the first direction at a predetermined angle, each of the plurality of scan lines and each of the plurality of data lines are located in the display area, and one end of each of the plurality of scan lines close to the fanout area is provided with a scan trace extending into the fanout area.

Each of the plurality of data lines is connected to a data bridging line, the data lines and the data bridging line are arranged in different layers, one end of the data bridging line is connected to the data line in the display area, and the other end of the data bridging line extends into the fanout area along the first direction.

In the display module provided by the embodiments of the present application, the driver substrate further comprises an insulating layer, each of the plurality of data lines is arranged on one side of the insulating layer, and the data bridging line is arranged on a side of the insulating layer away from the data line.

The insulating layer is defined with a plurality of via holes located in the display area, and each of the plurality of data lines correspondingly passes through one of the plurality of via holes and is connected to the data bridging line.

In the display module provided by the embodiments of the present application, each of the plurality of scan lines is arranged on a side of the insulating layer away from the data line, and each of the plurality of scan lines and the data bridging line are arranged on a same layer as an integrated structure.

In the display module provided by the embodiments of the present application, the display module further comprises a center line parallel to the first direction, each of the plurality of data lines is symmetrically arranged with the center line as a symmetry axis, the plurality of the data lines are divided into a plurality groups of data line in the first direction, and each of the plurality groups of data line comprises at least one of the plurality of data lines.

In two adjacent groups of data line, the via hole corresponding to one of the plurality groups of data line is located on one side of the center line, and the via hole corresponding to the other one of the plurality groups of data line is located on the other side of the center line. In the display module provided by the embodiments of the present application, the plurality groups of data line comprise one of the plurality of data lines.

Among the two adjacent groups of data line, a distance from the via hole corresponding to one of the plurality groups of data line close to the fanout area to the center line is greater than or equal to a distance from the via hole corresponding to one of the plurality groups of data line away from the fanout area to the center line.

In the display module provided by the embodiments of the present application, the plurality groups of data line comprise at least two of the plurality of data lines.

Among the two adjacent groups of data line, an average distance from each of the plurality of via holes corresponding to one of the plurality groups of data line close to the fanout area to the center line is greater than or equal to an average distance from each of the plurality of via holes corresponding to one of the plurality groups of data line away from the fanout area to the center line.

In the display module provided by the embodiments of the present application, among the two adjacent data lines in each of the plurality groups of data line, a distance from one of the plurality of via holes corresponding to the data line close to the fanout area to the center line is greater than a distance from the center line to one of the plurality of via holes corresponding to the data line away from the fanout area.

In the display module provided by the embodiments of the present application, at least one data bridging line is provided between two adjacent scan lines.

In the display module provided by the embodiments of the present application the driver substrate further comprises a bending area adjacent to the display area, and the fanout area is located in the bending area. Embodiments of the present application further comprises a display device comprising at least two display modules, wherein two adjacent display modules are arranged side by side along a first direction or a second direction, the display modules comprise a driver substrate, and the driver substrate comprises a display area and a fanout area that are arranged side by side along the first direction.

The driver substrate comprises a plurality of scan lines parallel to the first direction and a plurality of data lines parallel to a second direction, the second direction intersects the first direction and is arranged to be aligned with the first direction at a predetermined angle, each of the plurality of scan lines and each of the plurality of data lines are located in the display area, and one end of each of the plurality of scan lines close to the fanout area is provided with a scan trace extending into the fanout area.

Each of the plurality of data lines is connected to a data bridging line, the data lines and the data bridging line are arranged in different layers, one end of the data bridging line is connected to the data line in the display area, and the other end of the data bridging line extends into the fanout area along the first direction.

In the display device provided by the embodiments of the present application, wherein the driver substrate further comprises an insulating layer, each of the plurality of data lines is arranged on one side of the insulating layer, and the data bridging line is arranged on a side of the insulating layer away from the data line.

The insulating layer is defined with a plurality of via holes located in the display area, and each of the plurality of data lines correspondingly passes through one of the plurality of via holes and is connected to the data bridging line.

Advantageous Effect of Present Disclosure

### Advantageous Effect

The present application provides the following beneficial effects of. In embodiments of the present application, a scan trace extending into a fanout area is arranged on one end of each of the scan lines close to the fanout area and each of the data lines is connected to a data bridging line. The data lines and the data bridging line are arranged in different layers, and one end of the data bridging line is bridged with the data lines in the display area, and the other end of the data bridging line extends to the fanout area along a first direction, thereby facilitating the data line directly connected to the flexible circuit board at the fanout area through the data bridging line arranged in different layers, avoiding the need for data lines and scan lines to be routed to the fanout area through an area on a side of the display area, and reducing a frame width of a display module. Problems of a greater frame between two spliced display modules and unstable display images in the display device are thus solved.

### BRIEF DESCRIPTION OF DRAWINGS

### Description of Drawings

In order to more clearly illustrate technical solutions in embodiments of the present disclosure, a brief description of accompanying drawings used in a description of the embodiments will be given below. Obviously, the accompanying drawings in the following description are merely some embodiments of the present disclosure. For those skilled in the art, other drawings may be obtained from these accompanying drawings without creative labor.

FIG. 1 is a schematic diagram of a structure of a driver substrate in the prior art.

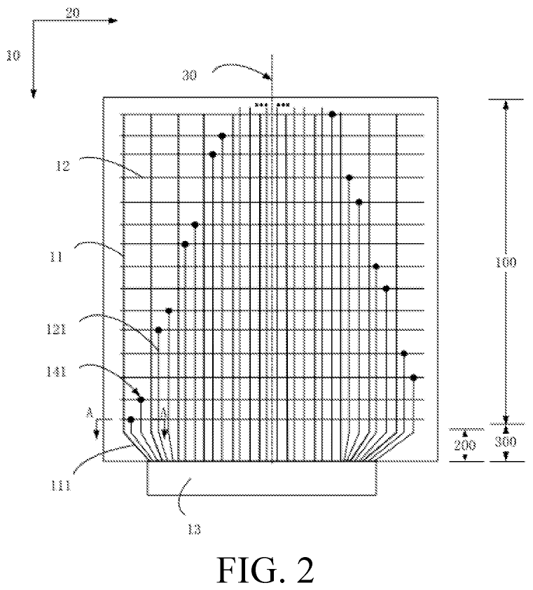

FIG. 2 is a schematic diagram of a first structure of a driver substrate provided by an embodiment of the application.

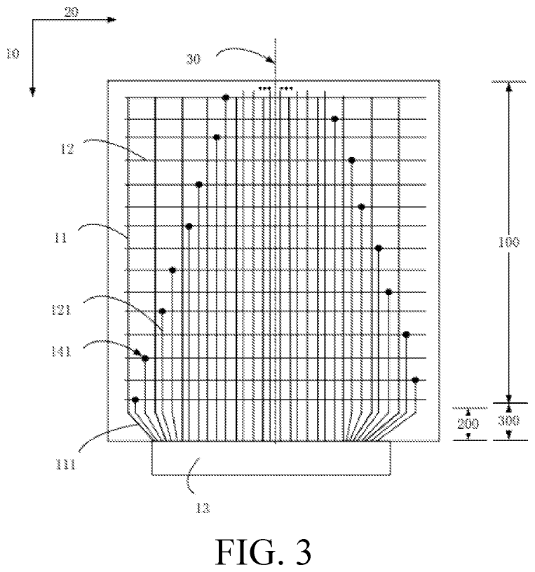

FIG. 3 is a schematic diagram of a second structure of a driver substrate provided by an embodiment of the application.

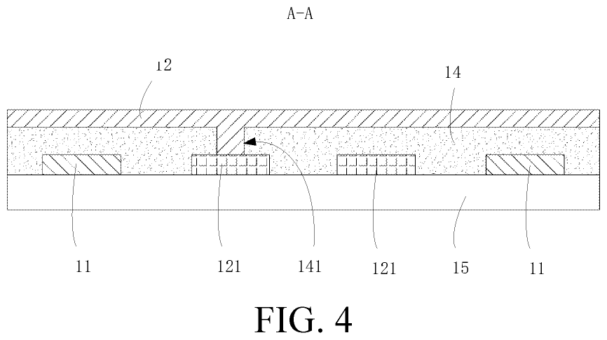

FIG. 4 is a schematic diagram of a cross-sectional structure at A-A in FIG. 2.

### DETAILED DESCRIPTION

### Detailed Description of Preferred Embodiments

In the description of the present disclosure, it should be understood that location or position relationships indicated by terms, such as “up”, “down”, “front”, “rear”, “left”, “right”, “inside”, “outside”, and “a side” are location or position relationships based on illustration of the accompanying drawings, are merely used for describing the present disclosure and simplifying the description instead of indicating or implying the indicated apparatuses or elements should have specified locations or be constructed and operated according to specified locations and should not be intercepted as limitations to the present disclosure. Furthermore, structural elements with same or similar characteristics may be indicated by same or different reference numerals in the present disclosure.

In the description of the present disclosure, terms such as “first” and “second” are used merely for description, but shall not be construed as indicating or implying relative importance or implicitly indicating a number of the indicated technical feature. Hence, the feature defined with “first” and “second” may explicitly or implicitly includes one or more such features. In the description of the present disclosure, a term “a plurality of” means “two or more” unless otherwise specifically limited.

In the description of this application, it should be noted that, unless otherwise clearly specified and limited, the terms “installation”, “connection”, and “connection” should be understood in a broad sense, for example, it can be a fixed connection or a detachable connection, or integrally connected. It can be mechanically connected, or it can be electrically connected or can communicate with each other. It can be directly connected, or indirectly connected through an intermediate medium. It can be the internal communication of two components or the interaction of two components relationship. For those of ordinary skill in the art, the specific meanings of the above-mentioned terms in this application can be understood according to specific circumstances.

The technical solution of the present application will now be described in conjunction with specific embodiments.

Referring to FIGS. 2 to 3, an embodiment of the present application provides a driver substrate, comprising a display area 100 and a fanout area 200 arranged in parallel along a first direction 10.

The driver substrate comprises a plurality of scan lines 11 parallel to the first direction 10 and a plurality of data lines 12 parallel to a second direction 20. The second direction 20 intersects the first direction 10 and is arranged at a predetermined angle to the first direction 10. Each of the plurality of scan lines 11 and each of the plurality of data lines 12 are located in the display area 100, and one end of each of the plurality of scan lines 11 close to the fanout area 200 is provided with a scan trace 111 extending into the fanout area 200.

Each of the plurality of data lines 12 is connected to a data bridging line 121. The data lines 12 and the data bridging line 121 are arranged in different layers. One end of the data bridging line 121 and the data lines 12 are connected in the display area 100. The other end of the data bridging line 121 extends into the fanout area 200 along the first direction 10.

It is noted that, as shown in FIG. 1, a driver substrate for a conventional splicing panel or splicing backlight in the prior art is illustrated. Due to a great number of data signal lines or driver signal lines is provided on a side of a frame 1 of the driver substrate, a width of a side of each display module in the splicing display is relatively large, resulting in a too large seam formed between display areas 100 of two display modules in the splicing display, and causes an unstable image display (i.e., mura) problem of the splicing display, which affects the display quality. In the present embodiment, one end of each of the plurality of scan lines 11 close to the collection area 200 is provided with a scan trace 111 extending into the fanout area 200, and each of the plurality of data lines 12 is connected to a data bridging line 121. The data lines 12 and the data bridging line 121 are arranged in different layers, one end of the data bridging line 121 is connected to the data line 12 in the display area 100, and the other end of the data bridging line 121 extends along the first direction 10 to the fanout area 200. Therefore, this internal structure is convenient for directly connecting the data lines 12 to, for example, a flexible circuit board 13 in the fanout area 200 through the data bridging line 121 arranged in different layers, avoiding a need for routing the data lines 12 and the scan lines 11 to pass through the side of the display area 100 to the fanout area 200, reducing a width of the frame of the display module, thereby also solving the problem of a large frame between two spliced display modules and unstable display images in the display device.

It is noted that the second direction 20 intersects the first direction 10 and is set to form a predetermined angle with the first direction 10. Obviously, the second direction 20 and the first direction 10 are formed in an intersected arrangement. That is, the second direction 20 is not parallel to the first direction 10, and the second direction 20 is arranged at a predetermined angle with the first direction 10. Specifically, the predetermined angle between the second direction 20 and the first direction 10 can be 90 degrees, one end of the data bridging line 121 is connected to the data lines 12 in the display area 100, and the other end of the data bridging line 121 extends into the fanout area 200 along the first direction 10. Herein, the other end of the data bridging line 121 extends into the fanout area 200 along the first direction 10, and the portion of the data bridging line 121 in the fanout area 200 can be arranged in a display arrangement such as a broken line or an arc line. That is, after the data bridging line 121 extends into the fanout area 200 along the first direction 10, it is also possible to extend along various different paths in the fanout area 200, which is not limited here. In addition, in the present embodiment, a flexible printed circuit (FPC) 13 is provided on a side of the driver substrate close to the fanout area 200. The scan line 11 is connected to the flexible circuit board 13 through the scan trace 111 extending into the fanout area 200, and the data line 12 is connected to the flexible circuit board 13 through the data bridging line 121 extending into the hub area 200.

In one embodiment, referring to FIG. 4, the driver substrate further comprises an insulating layer 14, each of the data lines 12 is disposed on a side of the insulating layer 14, and each of the data bridging lines 121 is disposed on a side of the insulating layer 14 away from the data line 12.

The insulating layer 14 is defined with a plurality of via holes 141 located in the display area 100, and each of the data lines 12 correspondingly passes through one of the plurality of the via holes 141 to connect one of the data bridging lines 121.

It is noted that the data lines 12 and the data bridging lines 121 are arranged in different layers to avoid interleaving and short-circuiting in the display area 100. That is, a wider frame problem caused by routing from a side of the driver substrate can also be avoided. In the present embodiment, the driver substrate further comprises an insulating layer 14. Each of the data lines 12 is arranged on a side of the insulating layer 14, and each of the data bridging lines 121 is arranged on a side of the insulating layer 14 away from the data lines 12 so as to realize the arrangement of the data lines 12 and the data bridging lines 121 in different layers. In addition, the insulating layer 14 is defined with a plurality of via holes 141 in the display area 100, and each data line 12 correspondingly passes through one of the via holes 141 to connect to one of the data bridging lines 121 so that one end of the data bridging line 121 is connected to the data line 12 in the display area 100. Specifically, referring to FIG. 4, the driver substrate further comprises a substrate 15, the data bridging line 121 is disposed on the substrate 15, the insulating layer 14 is disposed on the substrate 15 and the data bridging line 121 to cover the data bridging line 121, and the data line 12 is disposed on the insulating layer 14.

In one embodiment, referring to FIG. 4, each of the scan lines 11 is disposed on a side of the insulating layer 14 away from the data line 12, and each of the scan lines 11 and the data bridging line 121 are disposed on the same layer as an integrated structure.

It is noted that each of the scan lines 11 is arranged on a side of the insulating layer 14 away from the data line 12. That is, short-circuits due to a mesh-like interleaving of the scan lines 11 and the data lines 12 are prevented. Specifically, the scan line 11 and the data bridging line 121 are arranged on the same layer and form an integral structure. Obviously, routing of the scan line 11 and the data bridging line 121 are both arranged along the first direction 10, and each of the scan lines 11 and each of the data bridging lines 121 are arranged at intervals in the second direction 20. Please refer to FIG. 4, the data bridging lines 121 and the scan lines 11 are disposed on the substrate 15, and the insulating layer 14 is disposed on the substrate 15, the data bridging lines 121 and the scan lines 11 to cover the data bridging lines 121 and the scan lines 11. The data line 12 is arranged on the insulating layer 14 so as to arrange the scan lines 11 and the data bridging line 121 on the same layer, and the scan line 11 and the data bridging line 121 can be integrally formed on the same layer by the same manufacturing process. Narrowing and widening effects of the driver substrate can be thus realized without adding additional processes.

It is noted that the driver substrate further comprises a thin film transistor (TFT), and the thin film transistor (not shown in the figure) comprises a gate provided on the same layer as the scan lines 11 and the data bridging lines 121 and a source electrode and a drain electrode provided one the same layer as the data lines 12. Specifically, the thin film transistor may be a TFT structure such as a top gate structure, a bottom gate structure, etc., which is not limited herein.

In one embodiment, referring to FIGS. 2 to 3, the driver substrate further comprises a center line 30 parallel to the first direction 10. Each of the data lines 12 is symmetrically arranged with the center line 30 as an axis of symmetry. The plurality of data lines 12 are divided into a plurality of groups of data line 12 in the first direction 10, and each group of data line 12 comprises at least one data line 12.

Among the two adjacent groups of data line 12, the via 141 corresponding to one group of the data line 12 is located on one side of the center line 30, and the via hole 141 corresponding to the other group of data line 12 is located on the other side of the center line 30.

It is noted that the data line 12 is connected to a data bridging line 121 through a corresponding via hole 141 and receives a data signal. In this process, the closer to the position of the via hole 141 on each of the data lines 12, the smaller the impedance and the higher the charging efficiency. As a result, charging of the data lines 12 are not balanced, which leads to the problem of uneven display brightness and darkness. Obviously, by arranging two adjacent groups of the data line 12 on both sides of the center line 30 through the corresponding via holes 141, so that the unevenly charged positions of the two adjacent groups of the data line 12 can be interleaved and the bright and dark positions of the adjacent two groups of the data line 12 can be complementary to each other.

In one embodiment, referring to FIG. 3, the group of data line 12 comprises one data line 12. Among the two adjacent groups of data line 12, a distance from the via hole 141 corresponding to one group of the data line 12 close to the fanout area 200 to the center line 30 is greater than or equal to a distance from the via hole 141 corresponding to one group of the data line 12 away from the fanout area 200 to the center line 30.

It is noted that when the group of data line 12 comprises only one of the data lines 12, among two adjacent groups of data line 12, a distance from the via hole 141 corresponding to one group of the data line 12 close to the fanout area 200 to the center line 30 is greater than or equal to a distance from the via hole 141 corresponding to one group of the data line 12 away from the fanout area 200 to the center line 30. That is, the far of the distance from the via hole 141 corresponding to the groups of data line 12 close to the fanout area 200 to the center line 30 is, the near of the distance from the groups of data line 12 close to the fanout area 200 to the center line 30 obviously is. In addition, the far of the distance from the via hole 141 on the data line 12 to the center line 30 is, the more uneven charging on the data line 12 is. In the present embodiment, in each of the groups of data line 12, the far of the distance from the via hole 141 corresponding to the groups of data line 12 close to the fanout area 200 to the center line 30 is, that is, the near of the distance from the groups of data line 12 close to the fanout area 200 to the center line 30 obviously is so that the via hole 141 is arranged at a place close to the center line 30 when the data line far from the fanout area 200 is standing a greater impendence of the data bridging line 121. By forming a less distance difference from the via hole 141 to both ends of the data line 12, an impendence of the data line 12 away from the fanout area is reduced. Therefore, impendence differences to various data lines 12 of the driver substrate can be overall and maximumly reduced to ensure the image driving effects of the driver substrate.

Accordingly, please refer to FIG. 2, in the same way, when the groups of data line 12 comprise at least two data lines 12. Among the two adjacent groups of data line 12, an average distance from each of the via holes 141 corresponding to one group of the data line 12 close to the fanout area 200 to the center line 30 is greater than or equal to an average distance from the each of via holes 141 corresponding to one group of the data line 12 away from the fanout area 200 to the center line 30. Therefore, impendence differences to various data lines 12 of the driver substrate can be overall and maximumly reduced to ensure the image driving effects of the driver substrate, and details thereof are not described here again.

In one embodiment, please refer to FIG. 2, among the two adjacent data lines 12 in each of the group of data line 12, a distance from the via hole 141 corresponding to one group of the data line 12 close to the fanout area 200 to the center line 30 is greater than or equal to a distance from the via hole 141 corresponding to one group of the data line 12 away from the fanout area 200 to the center line 30. Obviously, in the same group of the group of the data line 12, by setting the distance from the via hole 141 corresponding to one of the two adjacent data lines 12 close to the data line 12 to the center line 30 to be greater than the distance from the via hole 141 corresponding to the other one of the two adjacent data lines 12 far away from the data line 12 to the center line 30, that is, by adjusting the positions of the via holes 141 corresponding to different data lines 12, impedance differences of various data lines caused by different distances of the corresponding data bridging lines from the fanout area 200 can be balanced.

In one embodiment, referring to FIGS. 2 to 3, at least one data bridging line 121 is provided between two adjacent scan lines 11. Specifically, the number of the data bridging lines 121 provided between two adjacent scan lines 11 can be specifically determined according to the ratio of the number of the data lines 12 to the scan lines 11 in practical applications, and is not limited here. In the present embodiment, at least one data bridging line 121 is provided between two adjacent scan lines 11, as shown in FIG. 2, or two data bridging lines 121 are provided between two adjacent scan lines 11, as shown in FIG. 3, and one data bridging line 121 is provided between the two scan lines 11. It should be noted that at least one data bridging line 121 is provided between two adjacent scan lines 11, and the number of the data bridging lines 121 between every two adjacent scan lines 11 is not the same.

In one embodiment, referring to FIGS. 2 to 3, the driver substrate further comprises a bending area 300 adjacent to the display area 100, and the fanout area 200 is located in the bending area 300. It is understandable that the driver substrate may further comprises a bending area 300, and the fanout area 200 is located in the bending area 300, so that the driver substrate is located on the flexible circuit board 13 after the fanout area 200 is connected, and it is then bent at the bending area 300 to bind the flexible circuit board 13 to the back of the driver substrate, so as to ensure that the four directions around the driver substrate can be spliced, which improves an applicability of the drive substrate in a splicing process.

Embodiments of the present application also provide a display module, comprising the driver substrate as described in the previous embodiments. It should be noted that the driver substrate in the display module can be used as a backlight or a display panel. The panel can be specifically arranged according to actual needs, so it will not described repeatedly here.

Embodiments of the present application also provide a display device. The display device comprises at least two display modules as described in the previous embodiments, and the two adjacent display modules are arranged side by side along the first direction 10 or the second direction 20.

In the present application, a scan trace 111 extending into the fanout area 200 is provided at one end of each scan line 11 close to the fanout area 200. In addition, through a structure of connecting each data line 12 with a data bridging line 121, arranging the data line 12 and the data bridging line 121 in different layers, bridging one end of the data bridging line with the data line in the display area 100, and extending the other end of the data bridging line into the fanout area 200, it is convenient for the data line 12 to be directly connected to the fanout area 200 such as the flexible circuit board 13 through the data bridging line 121 arranged in different layers, avoiding the need for routing the data line 12 and the scan line 11 to pass through the area on the side of the display area 100, reducing a frame width of the display module, thereby also solving the problem of a large frame between two spliced display modules and unstable display images in the display device.

The above is a detailed introduction to a mobile terminal provided by an embodiment of the present application. Specific examples are used in this article to illustrate the principles and implementation of the present application. Its core idea, at the same time, for those skilled in the art, according to the idea of this application, there will be changes in the specific implementation and scope of application. In summary, the content of the present specification should not be construed as a limitation to this application.

What is claimed is:

1. A driver substrate, comprising a display area and a fanout area arranged side by side along a first direction, wherein:
the driver substrate comprises a plurality of scan lines parallel to the first direction and a plurality of data lines parallel to a second direction, the second direction intersects the first direction and arranged to be aligned with the first direction at a predetermined angle, each of the plurality of scan lines and each of the plurality of data lines are located in the display area, and one end of each of the plurality of scan lines close to the fanout area is provided with a scan trace extending into the fanout area; and
each of the plurality of data lines is connected to a data bridging line, the data lines and the data bridging line are arranged in different layers, one end of the data bridging line is connected to the data line in the display area, and the other end of the data bridging line extends into the fanout area along the first direction.

2. The driver substrate according to claim 1, wherein the driver substrate further comprises an insulating layer, each of the plurality of data lines is arranged on one side of the insulating layer, and the data bridging line is arranged on a side of the insulating layer away from the data line; and
the insulating layer is defined with a plurality of via holes located in the display area, and each of the plurality of data lines correspondingly passes through one of the plurality of via holes and is connected to the data bridging line.

3. The driver substrate according to claim 2, wherein each of the plurality of scan lines is arranged on a side of the insulating layer away from the data line, and each of the plurality of scan lines and the data bridging line are arranged on a same layer as an integrated structure.

4. The driver substrate according to claim 2, further comprising a center line parallel to the first direction, each of the plurality of data lines is symmetrically arranged with the center line as a symmetry axis, the plurality of the data lines are divided into a plurality groups of data line in the first direction, and each of the plurality groups of data line comprises at least one of the plurality of data lines; and
in two adjacent groups of data line, the via hole corresponding to one of the plurality groups of data line is located on one side of the center line, and the via hole corresponding to the other one of the plurality groups of data line is located on the other side of the center line.

5. The driver substrate according to claim 4, wherein the plurality groups of data line comprise one of the plurality of data lines; and
among the two adjacent groups of data line, a distance from the via hole corresponding to one of the plurality groups of data line close to the fanout area to the center line is greater than or equal to a distance from the via hole corresponding to one of the plurality groups of data line away from the fanout area to the center line.

6. The driver substrate according to claim 4, wherein the plurality groups of data line comprise at least two of the plurality of data lines; and
among the two adjacent groups of data line, an average distance from each of the plurality of via holes corresponding to one of the plurality groups of data line close to the fanout area to the center line is greater than or equal to an average distance from each of the plurality of via holes corresponding to one of the plurality groups of data line away from the fanout area to the center line.

7. The driver substrate according to claim 6, wherein among the two adjacent data lines in each of the plurality groups of data line, a distance from one of the plurality of via holes corresponding to the data line close to the fanout area to the center line is greater than a distance from the center line to one of the plurality of via holes corresponding to the data line away from the fanout area.

8. The driver substrate according to claim 1, wherein at least one data bridging line is provided between two adjacent scan lines.

9. The driver substrate according to claim 1, wherein the driver substrate further comprises a bending area adjacent to the display area, and the fanout area is located in the bending area.

10. A display module, comprising a driver substrate, wherein the driver substrate comprises a display area and a fanout area arranged side by side along a first direction, wherein:
the driver substrate comprises a plurality of scan lines parallel to the first direction and a plurality of data lines parallel to a second direction, the second direction intersects the first direction and is arranged to be aligned with the first direction at a predetermined angle, each of the plurality of scan lines and each of the plurality of data lines are located in the display area, and one end of each of the plurality of scan lines close to the fanout area is provided with a scan trace extending into the fanout area; and
each of the plurality of data lines is connected to a data bridging line, the data lines and the data bridging line are arranged in different layers, one end of the data bridging line is connected to the data line in the display area, and the other end of the data bridging line extends into the fanout area along the first direction.

11. The display module according to claim 10, wherein the driver substrate further comprises an insulating layer, each of the plurality of data lines is arranged on one side of the insulating layer, and the data bridging line is arranged on a side of the insulating layer away from the data line; and
the insulating layer is defined with a plurality of via holes located in the display area, and each of the plurality of data lines correspondingly passes through one of the plurality of via holes and is connected to the data bridging line.

12. The display module according to claim 11, wherein each of the plurality of scan lines is arranged on a side of the insulating layer away from the data line, and each of the plurality of scan lines and the data bridging line are arranged on a same layer as an integrated structure.

13. The display module according to claim 11, further comprising a center line parallel to the first direction, each of the plurality of data lines is symmetrically arranged with the center line as a symmetry axis, the plurality of the data lines are divided into a plurality groups of data line in the first direction, and each of the plurality groups of data line comprises at least one of the plurality of data lines; and
in two adjacent groups of data line, the via hole corresponding to one of the plurality groups of data line is located on one side of the center line, and the via hole corresponding to the other one of the plurality groups of data line is located on the other side of the center line.

14. The display module according to claim 13, wherein the plurality groups of data line comprise one of the plurality of data lines; and
among the two adjacent groups of data line, a distance from the via hole corresponding to one of the plurality groups of data line close to the fanout area to the center line is greater than or equal to a distance from the via hole corresponding to one of the plurality groups of data line away from the fanout area to the center line.

15. The display module according to claim 13, wherein the plurality groups of data line comprise at least two of the plurality of data lines; and
among the two adjacent groups of data line, an average distance from each of the plurality of via holes corresponding to one of the plurality groups of data line close to the fanout area to the center line is greater than or equal to an average distance from each of the plurality of via holes corresponding to one of the plurality groups of data line away from the fanout area to the center line.

16. The display module according to claim 15, wherein among the two adjacent data lines in each of the plurality groups of data line, a distance from one of the plurality of via holes corresponding to the data line close to the fanout area to the center line is greater than a distance from the center line to one of the plurality of via holes corresponding to the data line away from the fanout area.

17. The display module according to claim 10, wherein at least one data bridging line is provided between two adjacent scan lines.

18. The display module according to claim 10, wherein the driver substrate further comprises a bending area adjacent to the display area, and the fanout area is located in the bending area.

19. A display device, comprising at least two display modules, wherein two adjacent display modules are arranged side by side along a first direction or a second direction, the display modules comprise a driver substrate, and the driver substrate comprises a display area and a fanout area that are arranged side by side along the first direction;
the driver substrate comprises a plurality of scan lines parallel to the first direction and a plurality of data lines parallel to a second direction, the second direction intersects the first direction and is arranged to be aligned with the first direction at a predetermined angle, each of the plurality of scan lines and each of the plurality of data lines are located in the display area, and one end of each of the plurality of scan lines close to the fanout area is provided with a scan trace extending into the fanout area; and
each of the plurality of data lines is connected to a data bridging line, the data lines and the data bridging line are arranged in different layers, one end of the data bridging line is connected to the data line in the display area, and the other end of the data bridging line extends into the fanout area along the first direction.

20. The display device according to claim 19, wherein the driver substrate further comprises an insulating layer, each of the plurality of data lines is arranged on one side of the insulating layer, and the data bridging line is arranged on a side of the insulating layer away from the data line; and
the insulating layer is defined with a plurality of via holes located in the display area, and each of the plurality of data lines correspondingly passes through one of the plurality of via holes and is connected to the data bridging line.
